(19) United States
(12) Patent Application Publication
(10) Pub. No.: US 2010/0025085 A1
(43) Pub. Date: Feb. 4, 2010

(54) ELECTRONIC APPARATUS, FLEXIBLE PRINTED WIRING BOARD AND METHOD FOR MANUFACTURING FLEXIBLE PRINTED WIRING BOARD

(75) Inventors: Yasuki Torigoshi, Tachikawa-shi (JP); Kiyomi Muro, Hachioji-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/421,411

(22) Filed: Apr. 9, 2009

(30) Foreign Application Priority Data
Jul. 31, 2008 (JP) 2008-198147

(51) Int. Cl. H05K 1/00; B44C 1/22

(52) U.S. Cl. 174/254; 216/13

(57) ABSTRACT

According to one embodiment, an electronic apparatus includes a casing and a flexible printed wiring board contained in the casing. The flexible printed wiring board includes an insulating layer, which is sheet-like, a signal line formed on a first surface of the insulating layer, and a ground layer, which is conductive and formed on a second surface of the insulating layer opposite to the first surface. The ground layer includes a mesh portion having a mesh structure and a thin film portion which fills cells in the mesh structure of the mesh portion.

### CROSS-REFERENCE TO RELATED APPLICATIONS

This application is based upon and claims the benefit of priority from Japanese Patent Application No. 2008-198147, filed Jul. 31, 2008, the entire contents of which are incorporated herein by reference.

### BACKGROUND

1. Field

One embodiment of the present invention relates to an electronic apparatus which includes a flexible printed wiring board having a ground layer, a flexible printed wiring board and a method for manufacturing a flexible printed wiring board.

2. Description of the Related Art

Jpn. Pat. Appln. KOKAI Publication No. 2007-227469 discloses a flexible printed wiring board having a ground layer of, for example, a mesh structure, to reduce EMI (Electro Magnetic Interference). The flexible printed wiring board comprises a flexible insulating layer, a mesh-like ground layer formed on one surface of the insulating layer, and a signal line formed on the other surface of the insulating layer.

In the flexible printed wiring board, the signal line is arranged so as not to be parallel to a line that connects intersections of the mesh structure. Therefore, impedance does not depend on the relative position between the signal line and the ground layer.

In the case of the conventional ground layer having the mesh structure as described above, the flexible printed wiring board can sufficiently be flexible. However, the ground layer of the mesh structure cannot have a sufficient electromagnetic shielding property because of its structure. Therefore, depending on the state of use, for example, if the flexible printed wiring board is located near a conductive member, unnecessary electromagnetic wave exceeding a reference value may leak outside. On the other hand, if the ground layer is formed of a sheet-like conductive layer, the electromagnetic shielding property may increase but the flexibility of the flexible printed wiring board may decrease.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view showing a portable computer according to a first embodiment of the present invention;

FIG. 2 is an exemplary perspective view showing a printed circuit board, a flexible printed wiring board and a hard disk device contained in a main body cabinet of the portable computer shown in FIG. 1;

FIG. 3 is an exemplary perspective view showing an opening of the main body cabinet to mount the hard disk device shown in FIG. 2;

FIG. 4 is an exemplary top view of the flexible printed wiring board shown in FIG. 3;

FIG. 5 is an exemplary sectional view of the flexible printed wiring board shown in FIG. 4 taken along a vertical direction;

FIG. 6 is an exemplary diagram showing an evaluation result of EMI of the flexible printed wiring board shown in FIG. 4;

FIG. 7 is an exemplary sectional view of a flexible printed wiring board of a portable computer according to a second embodiment of the present invention; and

FIG. 8 is an exemplary sectional view of a flexible printed wiring board of a portable computer according to a third embodiment of the present invention.

### DETAILED DESCRIPTION

Various embodiments according to the invention will be described hereinafter with reference to the accompanying drawings. In general, according to one embodiment of the invention, an electronic apparatus includes a casing and a flexible printed wiring board contained in the casing. The flexible printed wiring board includes an insulating layer, which is sheet-like, a signal line formed on a first surface of the insulating layer, and a ground layer, which is conductive and formed on a second surface of the insulating layer opposite to the first surface. The ground layer includes a mesh portion having a mesh structure and a thin film portion which fills cells in the mesh structure of the mesh portion.

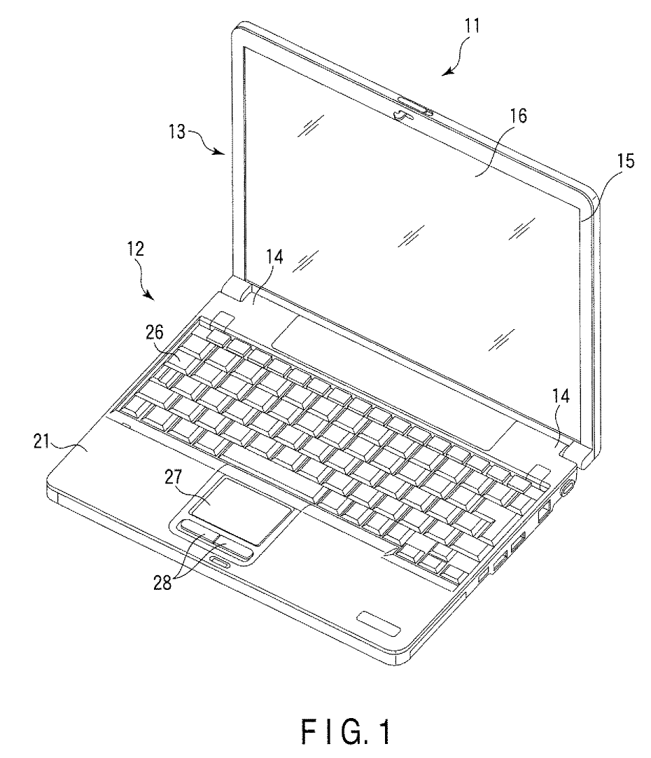

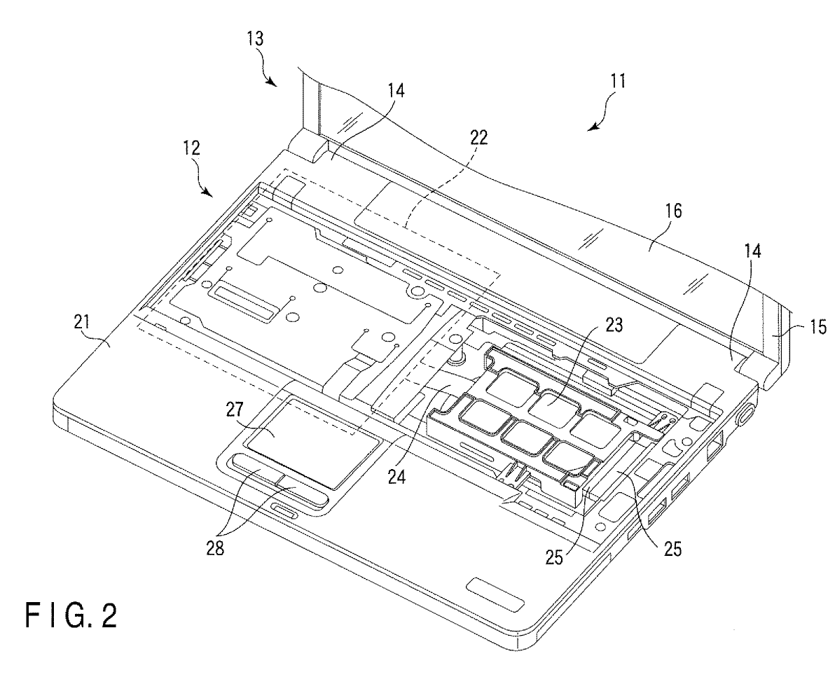

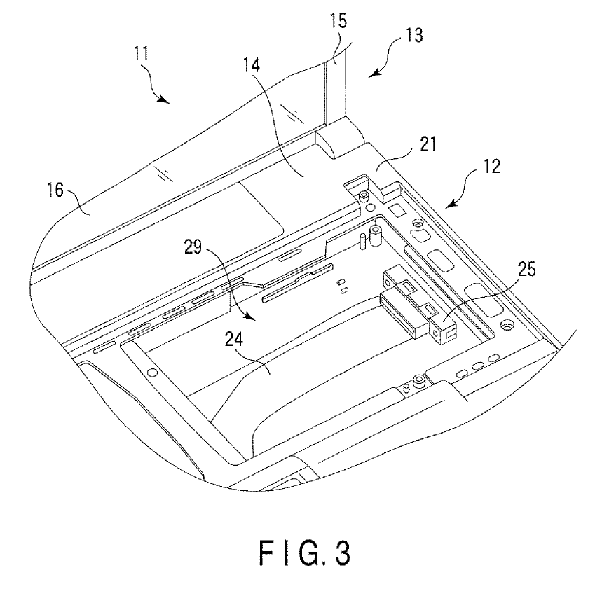

An embodiment of an electronic apparatus will be described below with reference to FIGS. 1 to 6. In this embodiment, the present invention is applied to a portable computer, a so-called notebook personal computer, as the electronic apparatus.

As shown in FIG. 1, a portable computer 11 comprises a main body unit 12, a display unit 13, hinge portions 14 provided between the main body unit 12 and the display unit 13. The hinge portions 14 rotatably support the display unit 13. The display unit 13 is supported by the hinge portions 14 so as to be rotatable between a closed position relative to the main body unit 12 and an open position relative to the main body unit 12.

As shown in FIG. 1, the display unit 13 comprises a display cabinet 15 and a liquid crystal display 16, as an example of the display, contained in the display cabinet 15.

As shown in FIGS. 1 to 3, the main body unit 12 comprises a main body cabinet 21 as a casing formed of a synthetic resin; a printed circuit board 22 and a hard disk device 23 contained in the main body cabinet 21; a flexible printed wiring board 24 and a connector 25 to electrically connect the printed circuit board 22 and the hard disk device 23; and a keyboard 26, a touch pad 27 and a button 28 mounted on the main body cabinet 21. The printed circuit board 22 has a plurality of circuit components, such as a CPU. The main body cabinet 21 has a rectangular opening 29 in which the hard disk device 23 is to be mounted.

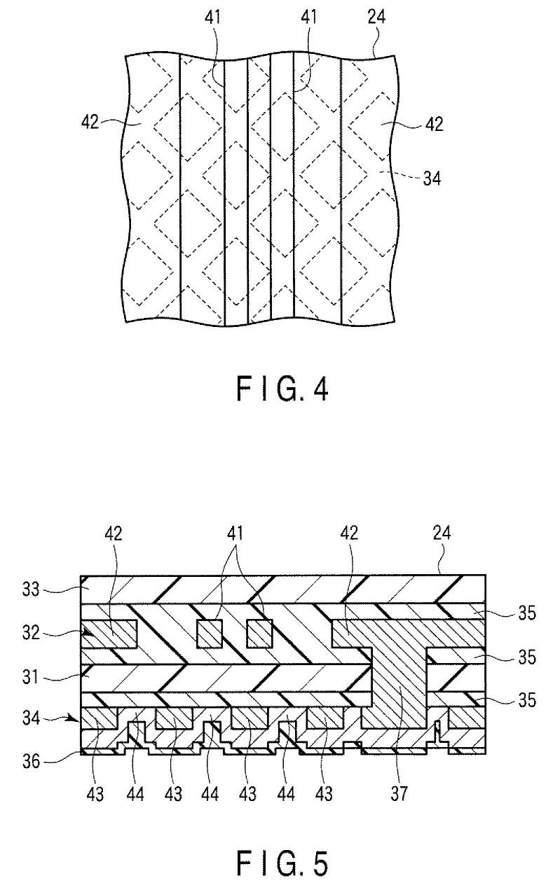

As shown in FIGS. 4 and 5, the flexible printed wiring board 24 has a sheet-like first insulating layer 31 serving as a base; a signal layer 32 formed on one surface of the first insulating layer 31; a second insulating layer 33 covering the outer surface of the signal layer 32; a conductive ground layer 34 formed on the other surface of the first insulating layer 31; adhesive layers 35 respectively interposed between the first insulating layer 31 and the signal layer 32, between the first insulating layer 31 and the ground layer 34 and between the signal layer 32 and the second insulating layer 33; a protective film 36 formed on the outer surface of the ground layer 34; and through hole plating 37 electrically connecting a copper foil portion 42 around a signal line 41 to the ground layer 34. The protective film 36 is formed of, for example, a synthetic resin.

The first insulating layer 31 and the second insulating layer 33 are formed of, for example, polyimide film. The signal layer 32 has the signal line 41 and the copper foil portion 42 around the signal line 41. The ground layer 34 has a mesh portion 43 and a thin film portion 44 provided in cells of the mesh structure in the mesh portion 43. The thin film portion 44 is provided to fill the cells of the mesh structure. The thin film portion 44 has a thickness of, for example, 10 to 22 nm. The thin film portion 44 is formed by, for example, thermosetting silver paste. Although the thickness of the thin film portion 44 is 10 to 22 nm in this embodiment, it may be within the range of, for example, 10 nm to 10 μm, in which case the electromagnetic shielding property can be fully exhibited without adversely affecting the flexibility of the flexible printed wiring board 24.

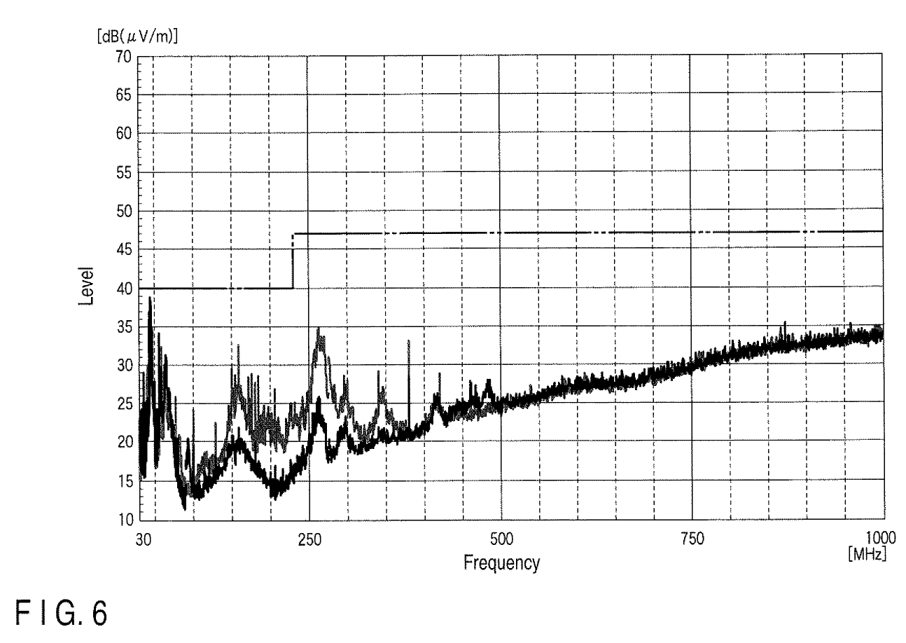

An evaluation result of EMI (Electro Magnetic Interference) using the flexible printed wiring board 24 of the embodiment will now be described with reference to FIG. 6. As shown in FIG. 6, the EMI emitted from the flexible printed wiring board 24 with both horizontal polarization and vertical polarization is less than the reference value indicated by the chain double-dashed line. With the conventional flexible printed wiring board having only a mesh-like ground layer, the EMI waveform having a pinpoint peak over the reverence value appears. In contrast, with the flexible printed wiring board 24 of this embodiment, it is confirmed that the occurrence of EMI is stably suppressed.

A method for manufacturing the flexible printed wiring board 24 of this embodiment will be described with reference to FIG. 5. In this flexible printed wiring board 24, the signal line 41 on one surface of the first insulating layer 31 serving as the base is formed by the known build-up process for forming general flexible printed wiring boards. The ground layer 34 on the other surface of the first insulating layer 31 is formed by the following sequences.

A sheet-like conductive layer is adhered to the other surface of the first insulating layer 31 with adhesive. Then, the conductive layer is subjected to etching with, for example, masking and formed into the mesh portion 43. A conductive material, such as silver paste, is applied to the mesh portion 43 from above by screen printing or the like. As a result, the conductive thin film portion 44 is formed. After the completion of this application process, the film portion 44 is heated to harden the silver paste, thereby forming the ground layer 34. The silver paste is formed by mixing silver as the conductive material with an organic material.

In this embodiment, the thin film portion 44 is formed in the cells of the mesh structure by screen printing. However, the method of forming the thin film portion 44 is not limited to this. The thin film portion 44 may be formed by depositing silver or copper from above the mesh portion 43 by sputtering, or by adhering a conductive shield film of, for example, silver, to the upper surface of the mesh portion 43.

According to the first embodiment, the portable computer 11 as an example of the electronic apparatus comprises the casing and the flexible printed wiring board 24 contained in the casing. The flexible printed wiring board 24 includes the sheet-like insulating layer, the signal line 41 formed on one surface of the insulating layer and the conductive ground layer 34 formed on the other surface, opposite to the one surface, of the insulating layer. The ground layer 34 includes the mesh portion 43 and the thin film portion 44 filled in the cells of the mesh portion 43.

The method for manufacturing the flexible printed wiring board 24 of this embodiment comprises forming the signal layer 32 on one surface of an insulating layer, forming a sheet-like conductive layer on the other surface of the insulating layer, etching the conductive layer into a mesh shape, and thereafter depositing conductive thin film portion 44 from above the mesh-shaped conductive layer, thereby forming the ground layer 34.

With the configurations described above, the ground layer 34 is formed as a semi-mesh shape by combining the mesh structure and the thin film portion 44 filled in the cells of the mesh structure. Thus, since the substantial part of the ground layer 34 is mesh-shaped, the flexibility of the flexible printed wiring plate 24 can be maintained. Further, since the cells of the mesh structure is filled with the thin film portion 44 to prevent transmission of electromagnetic waves, the signal line 41 of the flexible printed wiring board 24 can be prevented from being electromagnetically connected to the conductive material arranged around the flexible printed wiring board 24. Therefore, unwanted radiation (EMI) from the flexible printed wiring board 24 can be reduced. Accordingly, both the reduction of the EMI from the flexible printed wiring board 24 and the improvement of the flexibility can be achieved. Further, with the flexible printed wiring board 24 of this embodiment, an electronic apparatus which allows a more flexible design can be provided. More specifically, for example, connectors can be provided in various portions, top and bottom portions and left and right portions, of the electronic apparatus. Furthermore, a compact digital apparatus with the hinge portion 14, which can move in a wider range, can be developed.

In this case, the thin film portion 44 is formed by depositing conductive material from above the mesh portion 43 which has adhered in advance to the other surface of the insulating layer. This configuration allows easy formation of the thin film portion 44 by screen printing, sputtering or adhering of film-like conductive material.

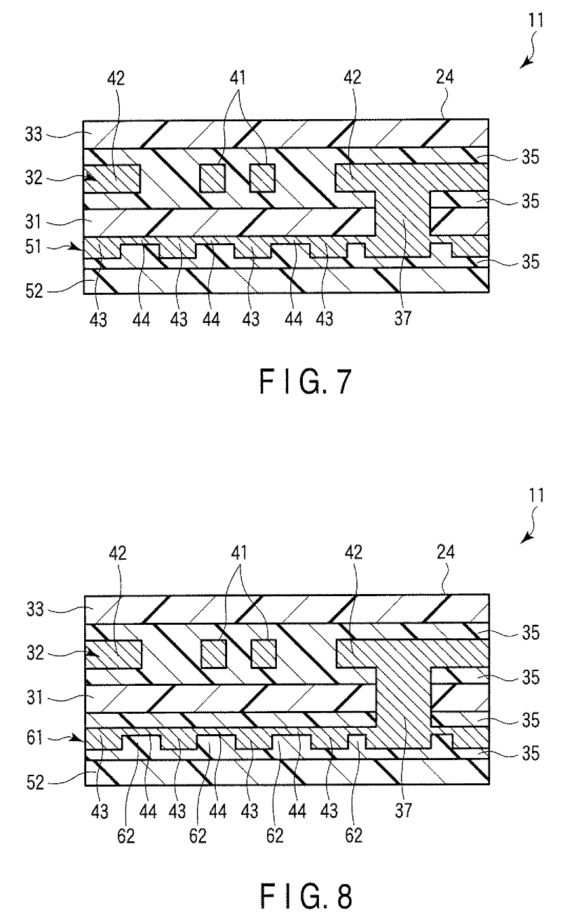

A second embodiment of the portable computer 11 will now be described with reference to FIG. 7. The second embodiment of the portable computer 11 as an example of the electronic apparatus is different from the first embodiment in the method of forming a ground layer 51 of the flexible printed wiring board 24, etc., but the same in the other respects. Therefore, the difference from the first embodiment will mainly be described below, and the same parts are identified by the same reference symbols and description thereof will be omitted.

As shown in FIG. 7, the flexible printed wiring board 24 has a first insulating layer 31 serving as a base; a signal layer 32 formed on one surface of the first insulating layer 31; a second insulating layer 33 covering the outer surface of the signal layer 32; a conductive ground layer 51 formed on the other surface of the first insulating layer 31; a third insulating layer 52 formed on the outer side of the ground layer 51; adhesive layers 35 respectively interposed between the first insulating layer 31 and the signal layer 32, between the signal layer 32 and the second insulating layer 33, and between the ground layer 51 and the third insulating layer 52; and through hole plating 37 electrically connecting a copper foil portion 42 around a signal line 41 to the ground layer 51.

The ground layer 51 has a mesh portion 43 and a thin film portion 44 provided in cells of the mesh structure in the mesh portion 43. The thin film portion 44 has a thickness of, for example, 50 to 100 nm. The thin film portion 44 is formed by, for example, sputtering copper onto the surface of the first insulating layer 31.

A method for manufacturing the flexible printed wiring board 24 of the second embodiment will be described. The signal line 41 is formed on one surface of the first insulating layer 31 by the known build-up process. A thin film portion (sputtering layer) 44 of, for example, copper is formed on the other surface of the first insulating layer 31 by sputtering. Thereafter, a plating resist is deposited on the thin film portion 44 as a mask and a mesh portion (plating metal layer) 43 is formed by plating on the thin film portion 44, thereby forming a ground layer 51.

In this embodiment, the thin film portion 44 is formed by sputtering. However, the method of forming the thin film portion 44 is not limited to this, but may be of other thin-film forming methods, such as deposition. The mesh portion 43 may be formed by either electrolytic plating or electroless plating. In evaluation of this embodiment, it was confirmed that EMI of the flexible printed wiring board 24 of this embodiment was less than the reference value as well as in the first embodiment.

In the second embodiment, the thin film portion 44 is a sputtering layer formed by subjecting the other surface of the insulating layer to sputtering. With this configuration, since it is unnecessary to interpose an adhesive layer between the insulating layer and the thin film portion 44 of the ground layer 51, the flexible printed wiring board 24 can be thinner and the flexibility of the flexible printed wiring board 24 is kept high. Further, since it is unnecessary to bond the first insulating layer 31 and the ground layer 51 to each other by adhesive, the process of manufacturing the flexible printed wiring board 24 can be simplified.

In this embodiment, the mesh portion 43 is a plating metal layer formed by plating the upper side of the sputtering layer. Since the sputtering layer is formed on the other surface of the insulating layer, the mesh portion 43 may be formed by either electrolytic plating or electroless plating.

Moreover, in the method for manufacturing a flexible printed wiring board of this embodiment, the signal layer 32 is formed on one surface of the insulating layer, and the conductive thin film is formed on the other surface of the insulating layer. Thereafter, the thin film is subjected to masking and then plating to form a mesh structure of conductive material, thereby forming the ground layer 51. In this configuration, since the thin film is first formed on the insulating layer, the mesh portion 43 can easily be formed on the thin film by either electrolytic plating or electroless plating. Therefore, the process of manufacturing the flexible printed wiring board 24 can be simplified as a whole.

A third embodiment of the portable computer 11 will now be described with reference to FIG. 8. The third embodiment of the portable computer 11 as an example of the electronic apparatus is different from the first embodiment in the method of forming a ground layer 61 of the flexible printed wiring board 24, etc. but substantially the same in the other respects. Therefore, the difference from the first embodiment will mainly be described below, and the same parts are identified by the same reference symbols and description thereof will be omitted.

As shown in FIG. 8, the flexible printed wiring board 24 has a first insulating layer 31 serving as a base; a signal layer 32 formed on one surface of the first insulating layer 31; a second insulating layer 33 covering the outer surface of the signal layer 32; a conductive ground layer 61 formed on the other surface of the first insulating layer 31; a third insulating layer 52 formed on the outer side of the ground layer 61; adhesive layers 35 respectively interposed between the first insulating layer 31 and the signal layer 32, between the signal layer 32 and the second insulating layer 33, between the first insulating layer 31 and the ground layer 61 and between the ground layer 61 and the third insulating layer 52; and through hole plating 37 electrically connecting a copper foil portion 42 around a signal line 41 to the ground layer 61.

The ground layer 61 has a mesh portion 43 and a thin film portion 44 provided in cells of the mesh structure in the mesh portion. The thin film portion 44 has a thickness of, for example, 50 to 100 nm. The ground layer 61 has recesses 62 above the thin film portion 44 in the cells of the mesh portion 43.

A method for manufacturing the flexible printed wiring board 24 of the third embodiment will be described. The signal line 41 is formed on one surface of the first insulating layer 31 by the known build-up process. Sheet-like conductive material is adhered to the other surface of the first insulating layer 31 by, for example, adhesive. Thereafter, an etching resist is deposited on the conductive material as a mask and etching is performed to form recesses 62 in the conductive material. Thus, the conductive material is etched to form a mesh structure. The etching is performed to leave the thin film portion 44 remain in the cells of the mesh structure. During this process, the process time of the etching and the amount of the etching solution which reacts with the conductive material are adjusted so that the thin film portion 44 remains in the cells of the mesh structure.

In evaluation of this embodiment, it was confirmed that EMI of the flexible printed wiring board 24 of this embodiment was less than the reference value as well as in the first embodiment.

In the third embodiment, the ground layer 61 has the recesses 62 formed by etching the parts corresponding to the cells of the mesh portion 43.

Further, in the method of manufacturing the flexible printed wiring board 24 of this embodiment, the signal layer 32 is formed on one surface of the insulating layer, and the sheet-like conductive thin film is formed on the other surface of the insulating layer. Thereafter, the conductive thin film is subjected to etching to form a mesh structure and is left in the cells of the mesh structure. Thus, the ground layer 61 is formed.

According to the configurations of the third embodiment, the flexible printed wiring board 24 with the ground layer 61 including the thin film portion 44 in the cells of the mesh structure can be produced by etching as well as in the first embodiment and the second embodiment.

The electronic apparatus of the present invention is not limited to the above embodiments. The present invention can be applied to various electronic apparatuses, not only portable computers but also cellular phones. Furthermore, the electronic apparatus of this invention may be variously modified within the spirit and scope of the invention.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An electronic apparatus comprising:
a casing; and
a flexible printed wiring board contained in the casing,
the flexible printed wiring board comprising:
an insulating layer, which is sheet-like;
a signal line formed on a first surface of the insulating layer; and
a ground layer, which is conductive and formed on a second surface of the insulating layer opposite to the first surface,
wherein the ground layer includes a mesh portion having a mesh structure and a thin film portion which fills cells in the mesh structure of the mesh portion and is in tight contact with the mesh portion.

2. The electronic apparatus of claim 1, wherein the thin film portion is formed by depositing conductive material from above the mesh portion, which has adhered to the second surface of the insulating layer.

3. The electronic apparatus of claim 1, wherein the thin film portion is a sputtering layer formed by sputtering on the second surface of the insulating layer.

4. The electronic apparatus of claim 3, wherein the mesh portion is a plating metal layer formed by plating on the sputtering layer.

5. The electronic apparatus of claim 1, wherein the ground layer has recesses formed by etching parts that correspond to the cells of the mesh portion.

6. A flexible printed wiring board comprising:
an insulating layer, which is sheet-like;
a signal line formed on a first surface of the insulating layer; and
a ground layer, which is conductive and formed on a second surface of the insulating layer opposite to the first surface,
wherein the ground layer includes a mesh portion having a mesh structure and a thin film portion which fills cells in the mesh structure of the mesh portion and is in tight contact with the mesh portion.

7. The flexible printed wiring board of claim 6, wherein the thin film portion is formed by depositing conductive material from above the mesh portion, which has adhered to the second surface of the insulating layer.

8. The flexible printed wiring board of claim 6, wherein the thin film portion is a sputtering layer formed by sputtering on the second surface of the insulating layer.

9. The flexible printed wiring board of claim 8, wherein the mesh portion is a plating metal layer formed by plating on the sputtering layer.

10. The flexible printed wiring board of claim 6, wherein the ground layer has recesses formed by etching parts that correspond to the cells of the mesh portion.

11. A method for manufacturing a flexible printed wiring board, the method comprising:
forming a signal line on a first surface of an insulating layer;
forming a conductive layer, which is sheet-like, on a second surface of the insulating layer;
etching the conductive layer into a mesh structure; and
thereafter directly depositing a conductive thin film portion from above the conductive layer having the mesh structure, thereby forming a ground layer.
